(19) United States
(12) Patent Application Publication
(10) Pub. No.: US 2018/0053867 A1
(43) Pub. Date: Feb. 22, 2018

(54) MULTILAYER FILM AND PHOTOVOLTAIC MODULE

(71) Applicant: E I DU PONT DE NEMOURS AND COMPANY, Wilmington, DE (US)

(72) Inventors: Alan F. Green, Wilmington, DE (US); Babak Hamzavy, Birmingham, AL (US); Steven William MacMaster, Springfield, PA (US)

(21) Appl. No.: 15/674,624

(22) Filed: Aug. 11, 2017

Related U.S. Application Data
(63) Continuation of application No. 62/375,604, filed on Aug. 16, 2016.

(51) Int. Cl. H01L 31/049; B32B 27/08; B32B 7/12; H01L 31/048

(52) U.S. Cl. CPC H01L 31/049; B32B 27/08; B32B 2307/7244; H01L 31/0481; B32B 2457/12; B32B 7/12

(57) ABSTRACT

In a first aspect, a multilayer film includes a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07. In a second aspect, a photovoltaic module includes a backsheet and an encapsulant layer. The backsheet includes a multilayer film including a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07. The encapsulant layer is adhered to the polymeric oxygen barrier layer.

### BACKGROUND OF THE INVENTION

### Field of the Disclosure

The present invention relates to multilayer films and photovoltaic modules.

### Description of the Related Art

Solar cells are used to produce electrical energy from sunlight, offering a more environmentally friendly alternative to traditional methods of electricity generation. These solar cells are built from various semiconductor systems which must be protected from environmental effects such as moisture, oxygen, and UV light. The cells are usually jacketed on both sides by protective layers of glass and/or plastic films forming a multilayer structure known as a photovoltaic (PV) module. Fluoropolymer films are recognized as an important component in photovoltaic modules due to their excellent strength, weather resistance, UV resistance, and moisture barrier properties. Especially useful in these modules are film composites of fluoropolymer film and polymeric substrate film which act as a backing sheet for the module. Such composites have traditionally been produced from preformed films of fluoropolymer, specifically polyvinyl fluoride (PVF), adhered to polyester substrate film, specifically polyethylene terephthalate. When fluoropolymer such as PVF is used as a backsheet for the PV module, its properties significantly improve the module life, enabling module warranties of up to 25 years. Fluoropolymer backsheets are frequently employed in the form of a laminate with polyethylene terephthalate (PET) films, typically with the PET sandwiched between two PVF films.

The PV industry is currently affected by a problem, identified as “snail trails” in the industry, that over time may affect the performance of PV modules. Snail trails are visual discolorations that are seen to propagate along the crystalline silicon (c-Si) cell surface within the module, and have been attributed to a chemical reaction between silver nanoparticles in cell grid lines with reducing agents found in encapsulant material, typically ethylene vinyl acetate (EVA), that is in contact with the cells and grid lines. This problem occurs when a crystalline silicon cell is damaged as a result of a mechanical stress. This stress can be related to installation or wind load or manufacturing of the cell or the module and result in a micro-crack in a protective layer of the module. These micro-cracks can result in environmental infiltration into the module that enable chemical reactions with module components. It has been suggested that at the interface between silver metallization and EVA encapsulant material, moisture ingress in the presence of an electrical field and at module operating temperatures (and possibly UV irradiation corrosion processes) can lead to migration of silver into the encapsulant layer where it can react with a variety of components used in the encapsulant layer (see, for example, Meyer et al., Energy Procedia 38 (2013) 498-505). As a result, backsheets with reduced water vapor transmission rates have been suggested to prevent the formation of snail trails in PV modules.

### SUMMARY

In a first aspect, a multilayer film includes a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07.

In a second aspect, a photovoltaic module includes a backsheet and an encapsulant layer. The backsheet includes a multilayer film including a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07. The encapsulant layer is adhered to the polymeric oxygen barrier layer.

The foregoing general description and the following detailed description are exemplary and explanatory only and are not restrictive of the invention, as defined in the appended claims.

### DETAILED DESCRIPTION

In a first aspect, a multilayer film includes a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07.

In one embodiment of the first aspect, the first fluoropolymer includes a fluoropolymer selected from the group consisting of homopolymers and copolymers of vinyl fluoride, vinylidene fluoride, tetrafluoroethylene, hexafluoropropylene, chlorotrifluoroethylene, fluoroethylene alkyl vinyl ether and mixtures thereof.

In another embodiment of the first aspect, the polymeric oxygen barrier layer is selected from the group consisting of ethylene vinyl alcohol copolymer, polyvinylidene chloride, polyvinyl alcohol, nylon, polyacrylonitrile, polychlorotrifluoroethylene and mixtures thereof.

In yet another embodiment of the first aspect, the polymeric substrate is selected from the group consisting of polyester, polyethylene, polypropylene, polyethylene terephthalate, polyethylene naphthalate, polyvinyl chloride, polyimide, polyimide.

In still yet another embodiment of the first aspect, the polymeric oxygen barrier layer is a film layer or a coating layer.

In a further embodiment of the first aspect, the multilayer film further includes a first adhesive layer between the polymeric substrate film and the polymeric oxygen barrier layer.

In still a further embodiment of the first aspect, the polymeric oxygen barrier layer includes an adhesive.

In yet a further embodiment of the first aspect, the multilayer film further includes a second adhesive layer adhered to the polymeric oxygen barrier layer on a side opposite the polymeric substrate film.

In still yet a further embodiment of the first aspect, the multilayer film further includes an encapsulant layer adhered to the polymeric oxygen barrier layer. In a specific embodiment, the encapsulant layer is selected from the group consisting of poly(vinyl butyral), ethylene vinyl acetate, poly(vinyl acetal), polyurethane, linear low density polyethylene, polyolefin block elastomers, ethylene acrylate ester copolymers, ionomers, silicone polymers, epoxy resins, and mixtures thereof.

In a second aspect, a photovoltaic module includes a backsheet and an encapsulant layer. The backsheet includes a multilayer film including a polymeric substrate film, a first fluoropolymer layer adhered to a first side of the polymeric substrate film and a polymeric oxygen barrier layer adhered to a second side of the polymeric substrate film. The multilayer film has an oxygen transmission rate of less than 4.0 cc/m²-day measured according to ASTM 1927-07. The encapsulant layer is adhered to the polymeric oxygen barrier layer.

Many aspects and embodiments have been described above and are merely exemplary and not limiting. After reading this specification, skilled artisans appreciate that other aspects and embodiments are possible without departing from the scope of the invention. Other features and advantages of the invention will be apparent from the following detailed description, and from the claims.

### Definitions

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet”, “layer” and “film” are used in their broad sense interchangeably. A “backsheet” is a sheet, layer or film on the side of a photovoltaic module that faces away from a light source, and is generally opaque.

“Encapsulant” means material used to encase the fragile voltage-generating solar cell layer to protect it from environmental or physical damage and hold it in place in a photovoltaic module. Encapsulant layers are conventionally positioned between the solar cell layer and the incident front sheet layer, and between the solar cell layer and the backsheet backing layer. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to frontsheets, backsheets, other rigid polymeric sheets and solar cell surfaces, and long term weatherability.

The term “copolymer” is used herein to refer to polymers containing copolymerized units of two different monomers (a dipolymer), or more than two different monomers.

### Polymeric Substrate Films

Polymeric substrate films may be selected from a wide range of polymers. In one embodiment, the polymeric substrate film is a polyester, a polyethylene, a polypropylene, a polyethylene terephthalate, a polyethylene naphthalate, a polyvinyl chloride, a polyamide or a polyimide. In one embodiment, the polymeric substrate film is a thermoplastic polymer, which may be desirable for its ability to withstand higher processing temperatures. In a specific embodiment, a polyester for the polymeric substrate film is selected from polyethylene terephthalate, polyethylene naphthalate and a co-extrudate of polyethylene terephthalate/polyethylene naphthalate.

Fillers may also be included in the substrate film, where their presence may improve the physical properties of the substrate, for example, higher modulus and tensile strength. They may also improve adhesion of the fluoropolymer coating to the polymeric substrate film. One exemplary filler is barium sulfate, although others may also be used.

### Fluoropolymer Layers

In one embodiment, a multilayer film may include a first fluoropolymer layer adhered to a first side of the polymeric substrate film. There are no specific restrictions on the fluoropolymer used in the first fluoropolymer layer. It can be any fluoropolymer known in the art, including homopolymers of fluorinated monomers, copolymers of fluorinated monomers, or copolymers of a fluorinated monomer and a non-fluorinated monomer, as long as monomer units derived from the fluorinated monomer in the copolymer account for more than about 20 percent by weight based on the overall weight of the copolymer, or from about 40 to about 99 percent by weight.

The fluoropolymer in the first fluoropolymer layer may, for example, be comprised of polyvinyl fluoride (PVF), polyvinylidene fluoride (PVDF), polytetrafluoroethylene (PTFE), hexafluoropropylene (HFP), polychlorotrifluoroethylene (PCTFE), ethylene-tetrafluoroethylene copolymer (ETFE), fluoroethylene-alkyl vinyl ether copolymer (FEVE), tetrafluoroethylene-hexafluoropropylene copolymer (FEP), tetrafluoroethylene/hexafluoropropylene/vinylidene fluoride terpolymer (THV), copolymers and terpolymers comprising polyvinyl fluoride and polytetrafluoroethylene, and the like. In one embodiment, fluoropolymers include PVF homopolymer or copolymers or PVDF homopolymer or copolymers.

Fluoropolymers suitable for use in the first fluoropolymer layer also include blends of two or more of the above polymers or copolymers. The first fluoropolymer layer may also include minor amounts of other polymers and/or additives. The second layer is preferably comprised of at least about 60 weight percent, or at least about 80 weight percent, or at least about 90 weight percent of one or more of the above fluoropolymers based on the total weight of the second layer. In one embodiment, the second layer may further include additives. Additives may include, for example, light stabilizer, UV stabilizers, thermal stabilizers, anti-hydrolytic agents, light reflection agents, pigments, titanium dioxide, dyes, and slip agents. Suitable fluoropolymer films are commercially available. For example, PVF film is sold by DuPont under the trade name Tedlar®.

In one embodiment, an additional fluoropolymer layer or layers may be adhered to a second side of the polymeric substrate film, between the first fluoropolymer layer and the polymeric substrate film, to the first fluoropolymer film on a side opposite the polymeric substrate film, or a combination thereof.

### Polymeric Oxygen Barrier Layer

In one embodiment, a multilayer film may include a polymeric oxygen barrier layer adhered to a second side of the polymeric substrate film. Incorporating a polymeric oxygen barrier layer into a multilayer film can greatly reduce the rate of transmission of oxygen to the metallization that is in contact with the encapsulant layer in a PV module, thus reducing the rate of oxygen-catalyzed chemical degradation due to reaction between silver metallization and reactive species in the encapsulant layer. A polymeric oxygen barrier layer may be suitably flexible to avoid damage by micro-cracking due to physical stresses on the module. In one embodiment, by placing a polymeric oxygen barrier layer on a side of the polymeric substrate film that is located further away from the exterior surface of the module (i.e., closer to the centrally located cells), the polymeric oxygen barrier layer is further protected from physical damage by the outside environment. Furthermore, locating a polymeric oxygen barrier layer on an interior side of the polymeric substrate film positions the layer in closer proximity to the encapsulant layer and can reduce oxygen permeation from the peripheral edges of the module.

In one embodiment, the polymeric oxygen barrier layer may be comprised of ethylene vinyl alcohol copolymer (EVOH), polyvinylidene chloride (PVDC), polyvinyl alcohol (PVOH), nylon, polyacrylonitrile (PAN), polychlorotrifluoroethylene (PCTFE) and mixtures thereof.

In one embodiment, the polymeric oxygen barrier layer can have a thickness in a range of from about 10 to about 50 μm, or from about 10 to about 40 μm, or from about 15 to about 35 μm.

In one embodiment, the polymeric oxygen barrier layer can be a film layer. When a polymeric oxygen barrier layer is a film layer, in one embodiment, it may be adhered to the polymeric substrate film using an adhesive. In another embodiment, a polymeric oxygen barrier layer that is a film layer may further comprise an adhesive blended into the film layer so that an additional adhesive is not needed to adhere the polymeric oxygen barrier layer to the polymeric substrate film. In one embodiment, the polymeric oxygen barrier layer can be a coating composition that is applied to polymeric substrate film and cured to form the polymeric oxygen barrier layer.

### Adhesives

In one embodiment, a multilayer film may include one or more adhesive. Useful adhesives may be those known in the art for adhering polymeric films. In one embodiment, an adhesive may include a urethane adhesive or an epoxy adhesive. Various known additives may be added to an adhesive to satisfy various requirements of the multilayer film. Suitable additives may include, for example, light stabilizer, UV stabilizers, thermal stabilizers, anti-hydrolytic agents, light reflection agents, pigments, titanium dioxide, dyes, and slip agents. There are no specific restrictions to the content of the additives, as long as the additives do not produce an adverse impact on the final adhesion properties of the multilayer film.

In one embodiment, an adhesive may be used in an adhesive layer to adhere a polymeric oxygen barrier layer to a polymeric substrate film. In another embodiment, an adhesive may be used in a polymeric oxygen barrier layer.

### Multilayer Film and Backsheet

In one embodiment, a multilayer film includes a polymeric substrate film, a first fluoropolymer layer adhered to a first side of the polymeric substrate film and a polymeric oxygen barrier layer adhered to a second side of the polymeric substrate film. In one embodiment, the multilayer film includes a first adhesive layer between the polymeric substrate film and the polymeric oxygen barrier layer. In one embodiment, the polymeric oxygen barrier layer includes an adhesive. In one embodiment, the multilayer film includes a second adhesive layer adhered to the polymeric oxygen barrier layer on a side opposite the polymeric substrate film. In one embodiment, the multilayer film includes an encapsulant layer adhered to the polymeric oxygen barrier layer.

In one embodiment, a multilayer film may be used as a backsheet for a photovoltaic module, providing long-term mechanical, electrical and other barrier protection to the sensitive solar cells within the module. In one embodiment, a backsheet comprises a multilayer film having an oxygen transmission rate of less than 4.0 cc/m²-day, or less than 2.0 cc/m²-day, or less than 1.0 cc/m²-day.

### Photovoltaic Module

A photovoltaic module may further comprise one or more frontsheet layers or film layers to serve as the light-transmitting substrate (also known as the incident layer). The light-transmitting layer may be comprised of glass or plastic sheets, such as, polycarbonate, acrylics, polyacrylate, cyclic polyolefins, such as ethylene norbornene polymers, metallocene-catalyzed polystyrene, polyamides, polyesters, fluoropolymers and the like and combinations thereof. Glass most commonly serves as the front sheet incident layer of the photovoltaic module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass depends on the intended use.

In one embodiment, an encapsulant layer of a photovoltaic module is comprised of ethylene methacrylic acid and ethylene acrylic acid, ionomers derived therefrom, or combinations thereof. Such encapsulant layers may also be films or sheets comprising poly(vinyl butyral) (PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. An encapsulant layer may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like.

In one embodiment, a process of manufacturing a photovoltaic module may include a vacuum lamination process. For example, the photovoltaic module constructs described above may be laid up in a vacuum lamination press and laminated together under vacuum with heat and standard atmospheric or elevated pressure. In an exemplary process, a glass sheet, a front encapsulant layer, a solar cell layer, a back encapsulant layer and a multilayer film that is a backsheet are laminated together under heat and pressure and a vacuum to remove air. Preferably, the glass sheet has been washed and dried. In an exemplary procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of about 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. General art edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the photovoltaic modules with backsheet comprising a multilayer film including polymeric oxygen barrier layer.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The concepts described herein will be further described in the following examples, which do not limit the scope of the invention described in the claims.

### Test Methods

### Water Vapor Transmission Rate

Water vapor transmission rate (WVTR) was measured using a PERMATRAN-W® Model 700 testing system (MOCON, Inc., Minneapolis, Minn.) according to ASTM F1249, under 100% RH, nitrogen gas flow rate of 10 cc/min and a temperature of 38° C.

### Oxygen Transmission Rate

Oxygen transmission rate (OTR) was measured using an OX-TRAN® Model 2/21 testing system (MOCON) according to ASTM F1927-07, at room temperature under 60% RH.

### Example 1 and Comparative Example 1

For Comparative Examples 1 (CE1), a laminate film of PVF(38 μm)/PET(125 μm)/EVA(100 μm) (TPE HD backsheet, Madico, Inc., Woburn, MA) was tested for WVTR and OTR. The laminate film includes adhesive layers (nominally 10 μm thick) between both the PVF and PET films and the PET and EVA films.

For Example 1 (E1), the film of CE1 was laminated to a 25 μm polymeric oxygen barrier layer film (EVAL™ EF-F EVOH, Kuraray America, Inc., Houston, Tex.) using an adhesive layer (a two-part urethane adhesive available from Bostik, Inc., Wauwatosa, Wis.) to form a PVF/PET/EVA/EVOH multilayer film that was tested for WVTR and OTR. The multilayer film had a total thickness of 300 μm after lamination.

### Example 2 and Comparative Example 2

For Comparative Examples 2 (CE2), a laminate film of PVF(38 μm)/PET(250 μm)/EVA(60 μm) (Solmate® VTPE backsheet, Taiflex Scientific Co., Inc., Taiwan) was tested for WVTR and OTR. The laminate film includes adhesive layers (nominally 10 μm thick) between both the PVF and PET films and the PET and EVA films.

For Example 2 (E2), the film of CE2 was laminated to a 25 μm polymeric oxygen barrier layer film (EVAL™ EF-F EVOH) using a urethane adhesive layer (Bostik) to form a PVF/PET/EVA/EVOH multilayer film that was tested for WVTR and OTR. The multilayer film had a total thickness of 380 μm after lamination.

### Example 3 and Comparative Example 3

For Comparative Examples 3 (CE3), a laminate film of PVF(25 μm)/PET(250 μm) (Tedlar® PV 2111, DuPont) was tested for WVTR and OTR. The laminate film include an adhesive layer (nominally 10 μm thick) between the PVF and PET films.

For Example 3 (E3), the film of CE3 was laminated to a 25 μm polymeric oxygen barrier layer film (EVAL™ EF-F EVOH) using a urethane adhesive layer (Bostik) to form a PVF/PET/EVOH multilayer film that was tested for WVTR and OTR. The multilayer film had a total thickness of 300 μm after lamination.

### Comparative Example 4

For Comparative Examples 4 (CE4), a laminate film of PVF(25 μm)/PET(250 μm)/PVF(25 μm) (ICOSOLAR® 2442, Isovoltaic AG, Austria) was tested for WVTR and OTR. The laminate film includes adhesive layers (nominally 10 μm thick) between the PVF and PET films.

Table 1 summarizes the WVTR and OTR of E1-E3 and CE1-CE4. Results shown for each example are the average of three samples. While the WVTR is modestly affected by the incorporation of a polymeric oxygen barrier layer in a multilayer film, the OTR is significantly reduced. Film thickness recited in the examples for individual film layers are the nominal thickness of those layers before lamination. Total thickness of multilayer films are as measured after lamination.

TABLE 1

| | WVTR | OTR |
|---|---|---|
| Example | (g/m²-day) | (cc/m²-day) |
| CE1 | 2.3 | 7.71 |
| E1 | 2.1 | 0.47 |
| CE2 | 2.1 | 4.23 |
| E2 | 1.9 | 0.56 |
| CE3 | 4.7 | 7.83 |
| E3 | 4.7 | 0.33 |
| CE4 | — | 4.53 |

Note that not all of the activities described above in the general description or the examples are required, that a portion of a specific activity may not be required, and one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that one or more modifications or one or more other changes can be made without departing from the scope of the invention as set forth in the claims below. Accordingly, the specification is to be regarded in an illustrative rather than a restrictive sense and any and all such modifications and other changes are intended to be included within the scope of invention.

Any one or more benefits, one or more other advantages, one or more solutions to one or more problems, or any combination thereof has been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all of the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any sub-combination. Further, reference to values stated in ranges include each and every value within that range.

What is claimed is:

1. A multilayer film comprising:
a polymeric substrate film;
a first fluoropolymer layer adhered to a first side of the polymeric substrate film; and
a polymeric oxygen barrier layer adhered to a second side of the polymeric substrate film, wherein the multilayer film has an oxygen transmission rate of less than 4.0 cc/m²-day measured according to ASTM 1927-07.

2. The multilayer film of claim 1, wherein the first fluoropolymer comprises a fluoropolymer selected from the group consisting of homopolymers and copolymers of vinyl fluoride, vinylidene fluoride, tetrafluoroethylene, hexafluoropropylene, chlorotrifluoroethylene, fluoroethylene alkyl vinyl ether and mixtures thereof.

3. The multilayer film of claim 1, wherein the polymeric oxygen barrier layer is selected from the group consisting of ethylene vinyl alcohol copolymer, polyvinylidene chloride, polyvinyl alcohol, nylon, polyacrylonitrile, polychlorotrifluoroethylene and mixtures thereof.

4. The multilayer film of claim 1, wherein the polymeric substrate is selected from the group consisting of polyester, polyethylene, polypropylene, polyethylene terephthalate, polyethylene naphthalate, polyvinyl chloride, polyamide, polyimide.

5. The multilayer film of claim 1, wherein the polymeric oxygen barrier layer is a film layer or a coating layer.

6. The multilayer film of claim 1, further comprising a first adhesive layer between the polymeric substrate film and the polymeric oxygen barrier layer.

7. The multilayer film of claim 1, wherein the polymeric oxygen barrier layer comprises an adhesive.

8. The multilayer film of claim 1, further comprising a second adhesive layer adhered to the polymeric oxygen barrier layer on a side opposite the polymeric substrate film.

9. The multilayer film of claim 1, further comprising an encapsulant layer adhered to the polymeric oxygen barrier layer.

10. The multilayer film of claim 9, wherein the encapsulant layer is selected from the group consisting of poly(vinyl butyral), ethylene vinyl acetate, poly(vinyl acetal), polyurethane, linear low density polyethylene, polyolefin block elastomers, ethylene acrylate ester copolymers, ionomers, silicone polymers, epoxy resins, and mixtures thereof.

11. A photovoltaic module comprising:
a backsheet, wherein the backsheet comprises a multilayer film comprising:
a polymeric substrate film;
a first fluoropolymer layer adhered to a first side of the polymeric substrate film; and
a polymeric oxygen barrier layer adhered to a second side of the polymeric substrate film, wherein the multilayer film has an oxygen transmission rate of less than 4.0 cc/m²-day measured according to ASTM 1927-07; and
an encapsulant layer adhered to the polymeric oxygen barrier layer.
